(19) United States
(12) Patent Application Publication
(10) Pub. No.: US 2018/0103559 A1
(43) Pub. Date: Apr. 12, 2018

(54) HEAT SINK ASSEMBLY

(71) Applicant: MANDO CORPORATION, Pyeongtaek-si (KR)

(72) Inventor: Seung Young PARK, Yongin-si (KR)

(21) Appl. No.: 15/723,894

(22) Filed: Oct. 3, 2017

(30) Foreign Application Priority Data
Oct. 7, 2016 (KR) 10-2016-0129560

(51) Int. Cl. H05K 7/20; H02K 9/22

(52) U.S. Cl. CPC H05K 7/209; H02K 9/22

(57) ABSTRACT

A heat sink assembly. The heat sink assembly includes a heat sink plate having a planar body part with an inclined wall formed in a central portion thereof and a plurality of heat sink fins each extending from the wall towards an edge portion of the body part while protruding perpendicularly to the body part, and a housing disposed below the heat sink plate and having an accommodation section accommodating the heat sink fins and a heat-outlet bent downwardly along a peripheral side of the accommodation section.

### CROSS REFERENCE TO RELATED APPLICATION

The present application claims priority from Korean Patent Application Number 10-2016-0129560 filed on Oct. 7, 2016, the entire contents of which are incorporated herein for all purposes by this reference.

### BACKGROUND

### Field

The present disclosure relates to a heat sink assembly.

### Description

Generally, an AC generator for a vehicle is connected to a crank shaft of an engine so as to generate a voltage in response to the driving force of the engine so that a charging voltage is supplied to a load or a battery during operations of the vehicle.

As the most widely used example of such a vehicular AC generator, a three-phase AC generator is provided, in which conventionally, three coils are independently wound so as to increase a voltage at low speed, and to generate a stable voltage at high speed.

Further, a vehicular AC generator is composed of a rotor and a stator, where the rotor is provided such that permanent magnets are attached to an outer surface of a rotor core at regular intervals, and the stator is provided so that three-phase coils for output are respectively wound around a stator core extending in a circumferential direction.

In such a vehicular AC generator, as the rotor rotates, magnetic flux from an N-pole returns to an S-pole through a stator core, creating a magnetic circuit, wherein the magnetic flux of the magnetic circuit interacts with the three-phase coils wound around the stator, inducing an AC voltage in windings of the stator.

Further, the vehicular AC generator includes an inverter that converts AC power generated by a motor into DC power, wherein the inverter has various circuit elements such as a switch element, or the like.

In the meantime, a great amount of heat is generated when the inverter converts AC power into DC power, so that the circuit elements in the inverter may be thermally damaged.

Thus, a conventional vehicular AC generator is provided with a heat sink plate and a heat sink fan to cool the inverter.

Specifically, a conventional inverter heat sink configuration is provided such that a through-hole is axially formed in the center of the inverter so that external air may be introduced into the center of the inverter and then to the edge of the inverter through the through-hole by the heat sink fan.

However, the conventional inverter heat sink configuration has problems in that the through-hole should be formed in the center of the inverter, and thus, the inverter has an increased size. Particularly, in the case of a high power bent-driven starter generator (BSG) using a relatively large inverter, such problems may be relatively serious.

Further, since the through-hole formed in the center of the inverter should be subjected to a relatively complex separate sealing process in order to prevent the introduction of moisture into the inverter, problems arise in terms of the number of manufacturing processes and cost increases in manufacturing such a vehicular AC generator.

### BRIEF SUMMARY

Various aspects of the present disclosure provide a heat sink assembly capable of efficiently dissipating heat from circuit elements of an inverter provided above a heat sink.

Other aspects of the present disclosure provide a heat sink assembly capable of minimizing the size of an inverter and integrating circuit elements into the minimized inverter.

Yet other aspects of the present disclosure provide a heat sink assembly capable of simplifying a closed structure of an inverter, thereby efficiently preventing the introduction of moisture into the inverter.

According to an aspect, a heat sink assembly may include: a heat sink plate having a planar body part with an inclined wall formed in a central portion thereof and a plurality of heat sink fins each extending from the wall towards an edge portion of the body part while protruding perpendicularly to the body part; and a housing disposed below the heat sink plate and having an accommodation section accommodating the heat sink fins and a heat-outlet bent downwardly along a peripheral side of the accommodation section.

The heat sink fins may be arranged in a radial pattern, and the inclined wall may have a downwardly convergent inclined shape.

The accommodation section may have a first opening in a region corresponding to the wall between the heat sink fins, and the heat-outlet may have a second opening in a region corresponding to the body part between the heat sink fins.

The housing may further have an extension portion extending outwardly from the accommodation section.

The wall may have a width greater than a height thereof, and circuit elements may be disposed above the heat sink plate, wherein the width of the wall is less than a length of the circuit elements.

The heat sink assembly may further include a heat sink fan disposed in the housing so as to be separate from the heat-outlet and the accommodation section.

The heat sink assembly may further include a motor winding disposed between the heat-outlet and the heat sink fan so as to be separate from the accommodation section and partially exposed through the second opening.

A distance between the accommodation section and the motor winding may be smaller than a distance between the accommodation section and the heat sink fan.

As set forth above, external air is continuously supplied to the body part between the heat sink fins, having an effect of efficiently cooling circuit elements disposed above the heat sink plate.

Further, there is no need to provide a through-hole in the center of the inverter to cool the circuit elements of the inverter, having effects of minimizing the size of the inverter and of integrating the circuit elements into the minimized inverter.

Furthermore, the closed structure of the inverter is simplified, having an effect of efficiently preventing the introduction of moisture into the inverter.

The configurations of the present disclosure have other features and advantages that will be apparent from, or are set forth in greater detail in the accompanying drawings, which are incorporated herein, and in the following Detailed Description of the Invention, which together serve to explain certain principles of the present disclosure.

### BRIEF DESCRIPTION OF THE DRAWINGS

The above and other objects, features and advantages of the present disclosure will be more clearly understood from the following detailed description when taken in conjunction with the accompanying drawings, in which:

FIG. 1 is a view illustrating an AC generator according to an embodiment of the present disclosure, wherein the AC generator is partially cut-away so that a heat sink assembly in the AC generator is visible;

FIG. 2 is a view illustrating a heat sink assembly according to an embodiment of the present disclosure;

FIG. 3 is a cross-sectional view of a body part of a heat sink plate between heat sink fins;

FIG. 4 is a view illustrating a housing according to an embodiment of the present disclosure; and

FIGS. 5 and 6 are cross-sectional views of the heat sink assembly cut between the heat sink fins.

### DETAILED DESCRIPTION

Hereinafter, reference will be made to the present disclosure in detail, embodiments of which are illustrated in the accompanying drawings and described below, so that a person having ordinary skill in the art to which the present disclosure relates could easily put the present disclosure into practice. It should be understood that the present disclosure is not limited to the following embodiments but various changes in forms may be made. Throughout the drawings, the same reference numerals and symbols will be used to designate the same or like components, and specific portions will be omitted for the sake of brevity.

It will be further understood that the terms “comprise”, “include”, “have”, etc. used in this specification, specify the presence of stated features, integers, steps, operations, elements, components, and/or combinations of them but do not preclude the presence or addition of one or more other features, integers, steps, operations, elements, components, and/or combinations thereof.

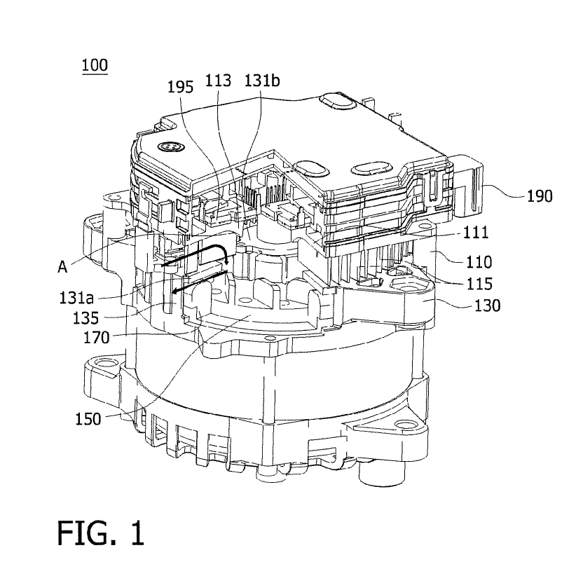

FIG. 1 is a view illustrating an AC generator according to an embodiment of the present disclosure, wherein the AC generator is partially cut-away so that a heat sink assembly in the AC generator is visible.

As illustrated in FIG. 1, the AC generator 100 includes an inverter 190, a heat sink plate 110, a housing 130, and a heat sink fan 150.

The inverter has various circuit elements 195 such as a switch element, or the like, and serves to convert AC power from a motor into DC power. A great amount of heat is generated when the inverter 190 converts the AC power into the DC power, so that the circuit elements in the inverter 190 may be thermally damaged.

Thus, in order to protect the circuit elements 195 from heat, a heat sink assembly including the heat sink plate 110, the housing 130, and the heat sink fan 150 is disposed below the inverter 190.

Specifically, the heat sink plate 110 has a body part 111 and heat sink fins 115, wherein the body part is centrally provided with a wall 113 having a downwardly convergent portion inclined in a curved “A” shape.

The housing 130 is disposed below the heat sink plate 110, has accommodation sections 131a and 131b in which the heat sink fins 111 are accommodated, and a heat-outlet 135 that is bent downwardly along a peripheral side of the accommodation section 131a.

The heat sink fan 150 is disposed in the housing such that the heat sink fan is separate from the heat-outlet 135 and the accommodation sections 131a and 131b of the housing 130. A motor winding 170 is disposed in a region between the heat-outlet 135 of the housing 130 and the heat sink fan 150 such that the motor winding is separate from the accommodation sections 131a and 131b of the housing 130.

The heat sink assembly operates as follows. As the heat sink fan 150 rotates, external air sequentially flows through the heat sink plate 110 along the body part 111 between the heat sink fins 115 from an edge portion towards a central portion thereof, as well as downwardly along the convergent inclined shaped (A) wall 113, and is discharged to the outside through a first opening between the accommodation sections 131a and 131b of the housing 130 and a second opening between the accommodation section 131a and the motor winding 170.

As such, since external air is continuously supplied to the body part 111 between the heat sink fins 115, the circuit elements 195 of the inverter 190 disposed above the heat sink plate 110 can be efficiently cooled.

That is, the AC generator according to embodiments of the present disclosure does not require a through-hole in the center of the inverter 190 for cooling the circuit elements 195 of the inverter 190, thereby minimizing the size of the inverter 190 and integrating the circuit elements 195 into the minimized inverter 190. Further, the inverter 190 has a simplified closed structure, thereby efficiently preventing the introduction of moisture into the inverter.

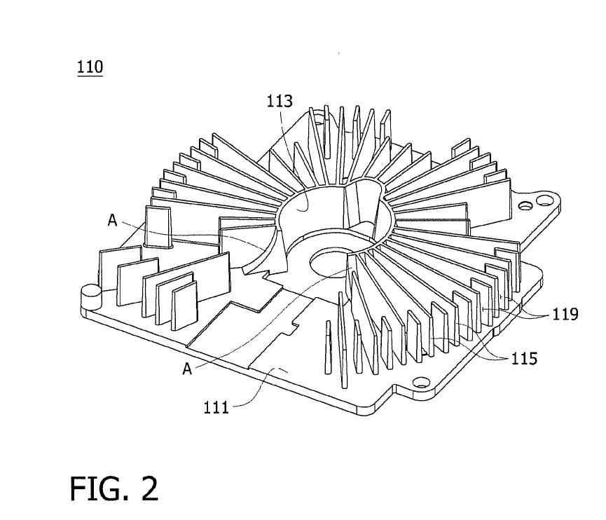

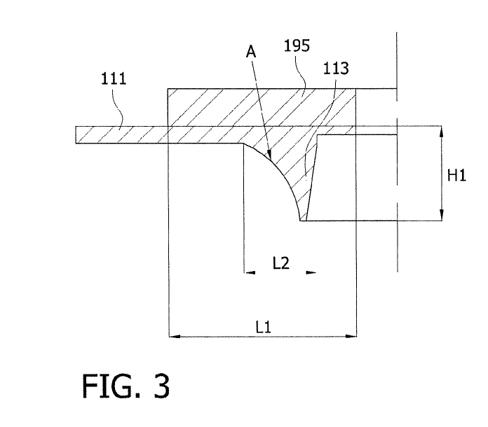

FIG. 2 is a view illustrating a heat sink assembly according to an embodiment of the present disclosure, and FIG. 3 is a cross-sectional view of the body part of the heat sink plate between heat sink fins.

As illustrated in FIG. 2, the heat sink plate 110 includes the body part 111, the wall 113, and the heat sink fins 115.

Specifically, the body part 111 has a planar shape, and is centrally provided with the wall 113 that protrudes in a convergent inclined shape (A). The heat sink fins 115 extend from the wall 113 towards the edge side of the body part 111 while protruding perpendicularly to the body part 111.

Here, the heat sink fins 115 may preferably be arranged in a radial pattern, and in this case, the wall 113 to which the heat sink fins are connected may have a circular wall surface. Spaces 119 between the heat sink fins 115 can serve as passages through which external air flows.

Due to the heat sink fins 115 provided on the lower side of the heat sink plate 110, the heat sink plate 110 has an increased surface area, which aids in efficiently cooling the circuit elements 195 of the inverter 190 provided above the heat sink plate 110.

The heat sink plate 110 may be formed of a high heat-conductive material such as aluminum, or the like.

The wall 113 preferably has a downwardly convergent outer portion with an inner portion thereof downwardly protruded perpendicular to the body part 111. This facilitates a flow of external air through passages between the heat sink fins 115 to naturally flow downwardly from the heat sink plate 110 along the downwardly convergent portion of the wall 113.

As illustrated in FIG. 3, the circuit elements 195 to be cooled are disposed above the heat sink plate 110, so that the circuit elements can be cooled by the heat sink plate 110.

Here, when a height H1 of the wall 113 is higher than a width L2 of the wall 113, the higher height of the wall 113 interferes with contact of the circuit elements 195 disposed above the wall 113 with external air, which makes it difficult to efficiently cool the circuit elements 195. Here, the height H1 of the wall 113 is a length of the wall in a vertical direction from the body part 111, and the width L2 of the wall 113 is a length of the wall in a horizontal direction of the along the body part 111.

Thus, the wall 113 has the downwardly convergent outer portion having an inclined shape A and preferably has the width L2 greater than the height H1. For example, the height H1 of the wall 113 may preferably have a range from 40% to 60% of the width L2 of the wall 113.

When the width L2 of the wall 113 is greater than a length L1 of the circuit element 195 disposed above the heat sink plate 110, external air flows downwardly along the wall 113 before cooling the circuit element 195, making it difficult to efficiently cool the circuit elements 195.

Thus, the width L2 of the wall 113 may preferably be smaller than the length L1 of the circuit element 195 disposed above the heat sink plate 110.

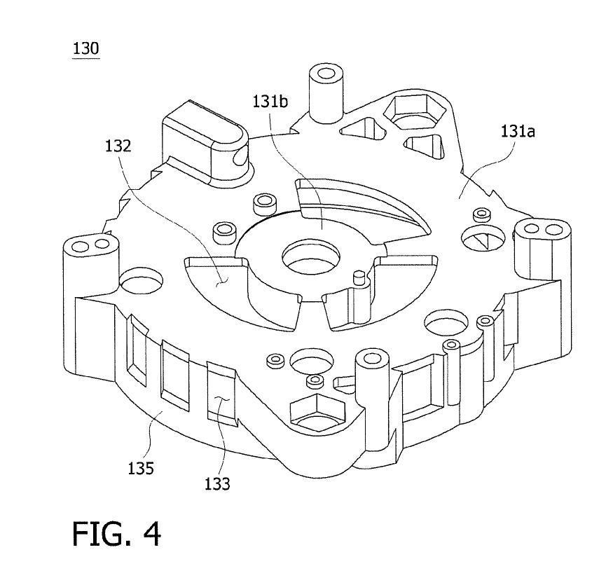

FIG. 4 is a view illustrating the housing according to an embodiment of the present disclosure.

As illustrated in FIG. 4, the housing 130 is disposed below the heat sink plate 110, and has the accommodation sections 131a and 131b in which the heat sink fins 115 and a leading end of the wall 113 are accommodated, and a heat-outlet 135 bent downwardly along a peripheral side of the accommodation section 131a. Here, the heat-outlet 135 surrounds a peripheral surface of the accommodation section 131a.

First openings 132 are provided between the accommodation sections 131a and 131b in a region corresponding to the wall 113 between the heat sink fins 115, and second openings 133 are provided in the heat-outlet 135 in a region corresponding to spaces 119 between the heat sink fins 115. The first and second openings 132 and 133 may communicate with each other.

Thus, when the heat sink fins 115 and the leading end of the wall 113 are accommodated in the accommodation sections 131a and 131b of the housing 130, air-flowing passages are formed in spaces 119 between the heat sink fins 115.

Here, since air flowing along the passage between the heat sink fins 115 flows downwardly from the heat sink plate 110 along the wall 113 and is then discharged to the outside through the first openings 132, the first openings 132 and the wall 113 should have a similar width. For example, the width of the first opening 132 may preferably have a range from 90% to 110% of the width of the wall 113.

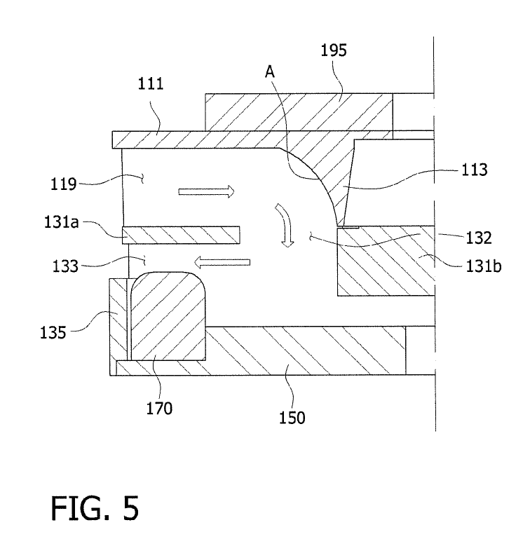

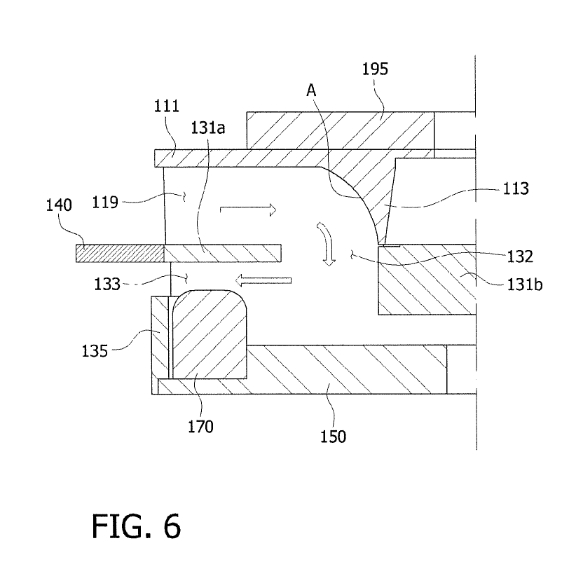

FIGS. 5 and 6 are cross-sectional views of the heat sink assembly cut between the heat sink fins.

As illustrated in FIGS. 5 and 6, the heat sink fan 150 is disposed in the housing 130 such that the heat sink fan is separate from the heat-outlet 135 and the accommodation sections 131a and 131b of the housing 120. Further, a motor winding 170 is disposed in a region between the heat-outlet 135 of the housing 130 and the heat sink fan 150 such that the motor winding is separate from the accommodation sections 131a and 131b of the housing 130. Here, the motor winding 170 may be partially exposed to the outside through the second openings 133 provided in the heat-outlet 135.

Thus, a discharge passage is defined by the accommodation sections 131a and 131b of the housing 130, the heat sink fan 150, and the motor winding 170.

In order to efficiently discharge hot air through the discharge passage, a distance between the accommodation section 131a and the motor winding 170 is preferably smaller than a distance between the accommodation section 131a and the heat sink fan 150. Particularly, the distance between the accommodation section 131a and the motor winding 170 may preferably be 3 mm to 6 mm.

The heat sink assembly operates as follows. As the heat sink fan 150 rotates, external air sequentially flows through the heat sink plate 110 along the body part 111, i.e. flowing passages defined by spaces 119 between the heat sink fins 115 of the heat sink plate 110 and the accommodation section 131a of the housing 130 from an edge portion towards a central portion thereof and downwardly from the heat sink plate 110 along the convergent inclined shaped (A) wall 113. Here, external air is supplied to the flowing passages of the heat sink plate 110 so as to cool the circuit elements 195 disposed above the heat sink plate 110.

Then, the air cooling the circuit elements 195 is heated by heat-exchange with the circuit elements 195, and the heated air flows downwardly through the first openings 132 from the heat sink plate 110 at the convergent inclined wall 113. Here, since the leading end of the wall 113 and the accommodation section 131b of the housing 130 are abutted against each other, the heated air flows not towards the circuit elements 195, but downwardly from the housing 130.

Then, the heated air flows through the discharge passages defined by the accommodation section 131a of the housing 130, the heat sink fan 150, and the motor winding 170, and is subsequently discharged to the outside through the second openings 133 of the heat-outlet 135.

In the meantime, the second openings 133 of the heat-outlet 135 may expose the peripheral portion of the accommodation section 131a of the housing 130 to the outside.

Here, the length of the accommodation sections 131a, 131b from a position where the accommodation section 131b and the wall 113 to the peripheral portion of the accommodation section 131b may preferably be similar to or larger than the length of the heat sink fins 115. For example, the length of the accommodation section 131a, 131b may range from 90% to 120% of the length of the heat sink fins 115.

This is because, when the length of the accommodation section 131a, 131b is smaller than the length of the heat sink fin 115, the discharged hot air may be reintroduced into the flowing passages defined by the heat sink fins 115 and the accommodation sections 131a, 131b, which degrades heat-dissipation performance of the heat sink plate 110.

In the meantime, as illustrated in FIG. 6, the housing 130 of the heat sink assembly may further include an extension portion 140 extending outwardly from the accommodation section 131a.

The extension portion 140 may be integrally formed with the accommodation section 131b of the housing 130 and the heat-outlet 135, or otherwise may be separately formed and attached to the accommodation section 131b of the housing 130.

In the case in which the extension portion 140 is attached to the accommodation section 131b of the housing 130, the extension portion 140 may be coupled to the peripheral portion of the accommodation section 131b exposed through the second openings 133.

With an additional provision of the extension portion, the length of the accommodation section 131a, 131b extends outwardly, preventing the discharged hot air from being reintroduced into the flowing passages defined by the heat sink fins 115 and the accommodation sections 131a, 131b, thereby improving the heat-dissipation performance of the heat sink plate 110.

As such, since external air is continuously supplied to flowing passages defined by spaces 119 between the heat sink fins 115, the body part 111, and the accommodation section 131a, the circuit elements 195 of the inverter 190 disposed above the heat sink plate 110 can be efficiently cooled.

That is, according to the heat sink assembly of the embodiments of the present disclosure, there is no need to provide a through-hole in the center of the inverter 190 to cool the circuit elements 195 of the inverter 190, having effects of minimizing the size of the inverter 190 and of integrating the circuit elements 195 into the minimized inverter 190. Thus, the heat sink assembly is applicable to a bent-driven starter generator (BSG) using a relatively large inverter.

Further, since there is no need to perform a complex sealing process on a central through-hole of the inverter 190, thereby simplifying the closed structure of the inverter 190 and thus efficiently preventing the introduction of moisture into the inverter. Accordingly, the number of the manufacturing processes and costs can be reduced in manufacturing a vehicular AC generator.

Although the specific embodiments of the present disclosure have been described for illustrative purposes, the scope of the present disclosure is limited by no means to the foregoing embodiments of the present disclosure. A person skilled in the art could easily make many other embodiments by adding, modifying, omitting, supplementing elements without departing from the principle of the present disclosure.

What is claimed is:

1. A heat sink assembly comprising:
a heat sink plate having a planar body part with an inclined wall formed in a central portion thereof and a plurality of heat sink fins each extending from the wall towards an edge portion of the body part while protruding perpendicularly to the body part; and
a housing disposed below the heat sink plate and having an accommodation section accommodating the heat sink fins and a heat-outlet bent downwardly along a peripheral side of the accommodation section.

2. The heat sink assembly according to claim 1, wherein the heat sink fins are arranged in a radial pattern.

3. The heat sink assembly according to claim 1, wherein the inclined wall has a downwardly convergent inclined shape.

4. The heat sink assembly according to claim 1, wherein the accommodation section has a first opening in a region corresponding to the wall between the heat sink fins, and wherein the heat-outlet has a second opening in a region corresponding to the body part between the heat sink fins.

5. The heat sink assembly according to claim 1, wherein the housing further has an extension portion extending outwardly from the accommodation section.

6. The heat sink assembly according to claim 1, wherein the wall has a width greater than a height thereof.

7. The heat sink assembly according to claim 1, wherein circuit elements are disposed above the heat sink plate, wherein the width of the wall is less than a length of the circuit elements.

8. The heat sink assembly according to claim 1, further comprising a heat sink fan disposed in the housing so as to be separate from the heat-outlet and the accommodation section.

9. The heat sink assembly according to claim 8, further comprising a motor winding disposed between the heat-outlet and the heat sink fan so as to be separate from the accommodation section and partially exposed through the second opening.

10. The heat sink assembly according to claim 9, wherein a distance between the accommodation section and the motor winding is smaller than a distance between the accommodation section and the heat sink fan.
